(19) United States
(12) Patent Application Publication
(10) Pub. No.: US 2026/0136846 A1
(43) Pub. Date: May 14, 2026

(54) SEMICONDUCTOR STACK, SEMICONDUCTOR DEVICE, AND METHOD OF MANUFACTURING SEMICONDUCTOR DEVICE

(71) Applicants: DENSO CORPORATION, Kariya-city (JP); TOYOTA JIDOSHA KABUSHIKI KAISHA, Toyota-shi (JP); MIRISE Technologies Corporation, Nisshin-shi (JP)

(72) Inventors: Kenta WATANABE, Nisshin-shi (JP); Hiroki MIYAKE, Nisshin-shi (JP); Kazuki IKEYAMA, Nisshin-shi (JP); Meguru ENDO, Nisshin-shi (JP)

(21) Appl. No.: 19/329,030

(22) Filed: Sep. 15, 2025

(30) Foreign Application Priority Data
Nov. 14, 2024 (JP) 2024-199062

(51) Int. Cl. H01L 21/02; H10D 30/01; H10D 30/66; H10D 62/85; H10D 62/852

(52) U.S. Cl. CPC H10P 14/3416; H10D 30/0291; H10D 30/66; H10P 14/3822; H10D 62/8503; H10D 62/852

(57) ABSTRACT

A semiconductor stack includes a nitride semiconductor layer containing a dopant, and a protective layer covering a surface of the nitride semiconductor layer. The protective layer is provided to suppress the dissociation of nitrogen from the nitride semiconductor layer during annealing. The protective layer is formed not to contain oxygen as a constituent element, and has higher oxygen barrier property than an aluminum nitride layer, to restrict action of oxygen on the surface of the nitride semiconductor layer.

### CROSS REFERENCE TO RELATED APPLICATION

This application is based on Japanese Patent Application No. 2024-199062 filed on Nov. 14, 2024, the disclosure of which is incorporated herein by reference.

### TECHNICAL FIELD

The present disclosure relates to a semiconductor stack, a semiconductor device, and a method of manufacturing a semiconductor device.

### BACKGROUND

In a method for producing a p-type group III nitride semiconductor, magnesium (Mg) is ion-implanted into a group III nitride semiconductor.

### SUMMARY

According to an aspect of the present disclosure, a semiconductor stack includes: a nitride semiconductor layer containing a dopant; and a protective layer covering a surface of the nitride semiconductor layer. The protective layer may be formed not to contain oxygen as a constituent element and have an oxygen barrier property higher than that of an aluminum nitride layer, thereby restricting action of oxygen on the surface.

### BRIEF DESCRIPTION OF DRAWINGS

FIG. 1 is a schematic cross-sectional view showing a semiconductor device.

FIG. 2 is a schematic cross-sectional view showing a semiconductor stack according to a first embodiment.

FIG. 3 is a diagram showing a part of a manufacturing flow corresponding to a method for manufacturing the semiconductor device shown in FIG. 1.

FIG. 4 is a schematic cross-sectional view showing a semiconductor stack according to a second embodiment.

FIG. 5 is a schematic cross-sectional view showing a semiconductor stack according to a third embodiment.

### DETAILED DESCRIPTION

In a method for producing a p-type group III nitride semiconductor, magnesium (Mg) is ion-implanted into a group III nitride semiconductor. Specifically, the method includes a step of forming a through-film, a step of implanting ion, a step of completely removing the through-film, a step pf forming a protective film, an annealing step, and a step of removing the protective film.

In the through-film formation step, a through-film is formed on a semiconductor layer composed of a group III nitride semiconductor. The through-film is used to adjust the amount of p-type impurity injected and the position of the injection peak in the subsequent step. In the ion implantation step, a p-type impurity is ion-implanted from the upper side of the through-film, with the implantation energy controlled such that the implantation peak is located within the through-film, thereby forming an ion-implanted region in the semiconductor layer.

In the protective film formation step, a protective film is formed on the semiconductor layer to restrict the dissociation of nitrogen during annealing in the subsequent step. The protective film may be formed of, for example, aluminum nitride (AlN), silicon nitride (SiN), silicon oxide (SiO₂), aluminum oxide (Al₂O₃), or the like. In the annealing step, the p-type impurity is activated by heat treatment to convert the ion-implanted region into a p-type region.

In this regard, as a result of the inventors' intensive research, it has been found that, in the conventional technology, there is still room for improvement in the protective effect on the surface of the nitride semiconductor layer during annealing. That is, there is still room for improvement in the effect of suppressing the dissociation of nitrogen. The present disclosure has been made in view of the circumstances exemplified above.

According to an aspect of the present disclosure, a semiconductor stack includes: a nitride semiconductor layer containing a dopant; and a protective layer covering a surface of the nitride semiconductor layer. The protective layer is formed not to contain oxygen as a constituent element, and has an oxygen barrier property higher than that of an aluminum nitride layer, thereby restricting action of oxygen on the surface.

According to another aspect of the present disclosure, a semiconductor stack includes: a nitride semiconductor layer containing a dopant; and a protective layer covering the nitride semiconductor layer. The nitride semiconductor layer is composed of gallium nitride or aluminum gallium nitride. The protective layer is made of a material of i) a gallium nitride layer; or ii) a carbon film and a cap layer stacked on the carbon film. The cap layer is made of a compound semiconductor material.

According to another aspect of the present disclosure, a semiconductor device includes: a semiconductor layer including a nitride semiconductor; and an electrode formed on a surface of the semiconductor layer having a surface roughness Ra of 5 nm or less.

According to another aspect of the present disclosure, a method of manufacturing a semiconductor device includes: forming a protective layer to cover a surface of a nitride semiconductor layer into which a dopant is ion-implanted; and annealing by heat treatment on the nitride semiconductor layer while being protected by the protective layer. In the step of forming the protective layer, the protective layer is formed not to contain oxygen as a constituent element and to have a higher oxygen barrier property than an aluminum nitride layer, to inhibit the action of oxygen on the surface.

Embodiments of the present disclosure will be described below with reference to the drawings as appropriate. It should be noted that the following embodiments, their modifications, and the accompanying drawings are schematically or simplistically illustrated in order to concisely explain the contents of the present disclosure. Therefore, the present disclosure is in no way limited by these descriptions. Accordingly, it should be understood that the configurations depicted in the drawings do not necessarily correspond to the specific device configurations that are actually manufactured and sold. That is, unless the applicant expressly limits the present application during its prosecution, the present disclosure should not be construed in a limiting manner based on the contents of the drawings, or the descriptions of the configurations, functions, or operations corresponding thereto as explained below.

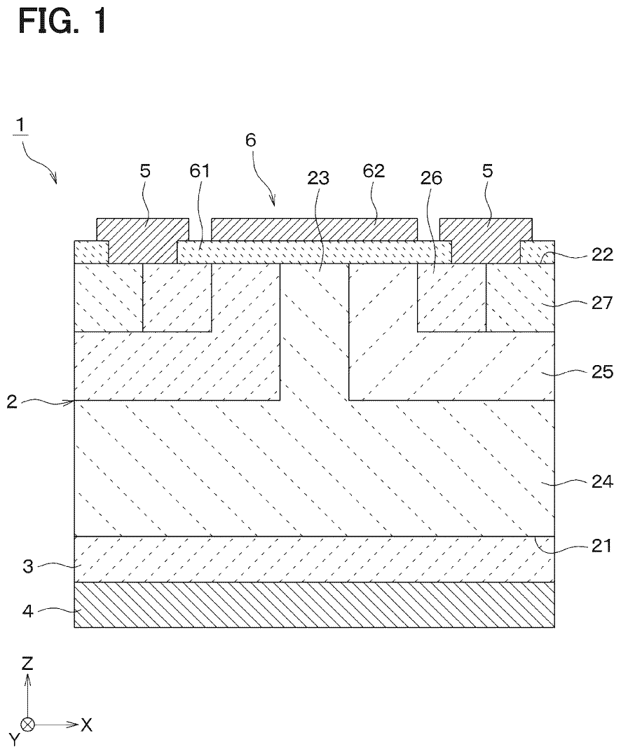

A schematic configuration of a semiconductor device 1 will be described with reference to FIG. 1. The semiconductor device 1 includes a semiconductor layer 2, a substrate 3, a drain electrode 4, a source electrode 5, and an insulation gate 6.

For the sake of simplification of illustration and description, a right-handed XYZ coordinate system is established as shown in FIG. 1. The Z direction is referred to as a vertical direction, and any direction within the XY plane is referred to as a plane direction. However, in this context, the concepts of vertical direction, up, and down are based solely on the up-down direction as depicted in the drawings, and do not necessarily correspond to the direction of gravity during the manufacturing process or use of the semiconductor device 1.

The semiconductor layer 2 is a compound semiconductor layer containing a nitride semiconductor, and has a lower surface 21 and an upper surface 22, as a main surface of a layered or plate-like object that is perpendicular to the thickness direction. The semiconductor layer 2 is provided such that the lower surface 21 is in contact with the substrate 3. The substrate 3 functions as a drain region containing a high concentration of n-type dopant, and is in ohmic contact with the drain electrode 4.

In the present embodiment, the semiconductor layer 2 is composed of gallium nitride and/or aluminum gallium nitride, and is formed on the substrate 3 using a crystal growth technique. The semiconductor layer 2 includes a drift region 24 containing a JFET region 23, a body region 25, a source region 26, and a body contact region 27.

The JFET region 23 is a part of the n-type drift region 24, and is formed in a protruding shape protruding upward to reach the upper surface 22 and come into contact with the insulation gate 6. A layered portion of the drift region 24 other than the JFET region 23 is provided in the lower part of the semiconductor layer 2 in the vertical direction to be in contact with the substrate 3.

The body region 25 is provided in contact with the layered portion of the drift region 24 other than the JFET region 23. A portion of the body region 25 adjacent to the JFET region 23 in the plane direction is formed in a protruding shape protruding upward to reach the upper surface 22 and come into contact with the insulation gate 6. The body region 25 contains a p-type dopant (for example, magnesium or the like).

The source region 26 and the body contact region 27 are provided in contact with the layered portion of the body region 25 other than the protruding portion. The source region 26 and the body contact region 27 are formed to reach the upper surface 22.

The source region 26 is provided in contact with the insulation gate 6 at a position, in the plane direction, adjacent to the protruding portion of the body region 25. The source region 26 contains an n-type dopant at a higher concentration than the drift region 24.

The body contact region 27 is provided, in the plane direction, at a position adjacent to the source region 26. The body contact region 27 contains a p-type dopant at a higher concentration than the body region 25. The body contact region 27 is in ohmic contact with the source electrode 5 adjacent to the upper surface 22.

In the present embodiment, the insulation gate 6 has a so-called planar structure. Specifically, the insulation gate 6 includes an insulating film 61 and a gate electrode 62. The insulating film 61 is formed as a flat film on the upper surface 22. The gate electrode 62 is provided as a flat layer or film to face, with the insulating film 61 interposed therebetween, the protruding portions of the JFET region 23 and the body region 25, as well as the source region 26.

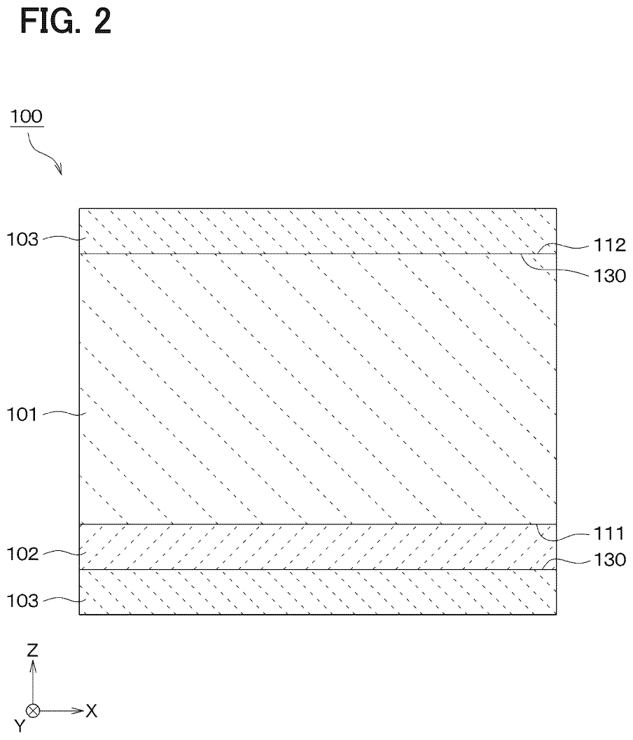

The schematic configuration of the semiconductor device 1 is the same as that disclosed in JP 2024-64553 A, which is incorporated by reference. In the semiconductor device 1 according to the present embodiment, the surface roughness Ra of the upper surface 22 is 5 nm or less. Such smoothness of the upper surface 22 can be achieved in the manufacturing process of the semiconductor device 1 by using the semiconductor stack 100 shown in FIG. 2.

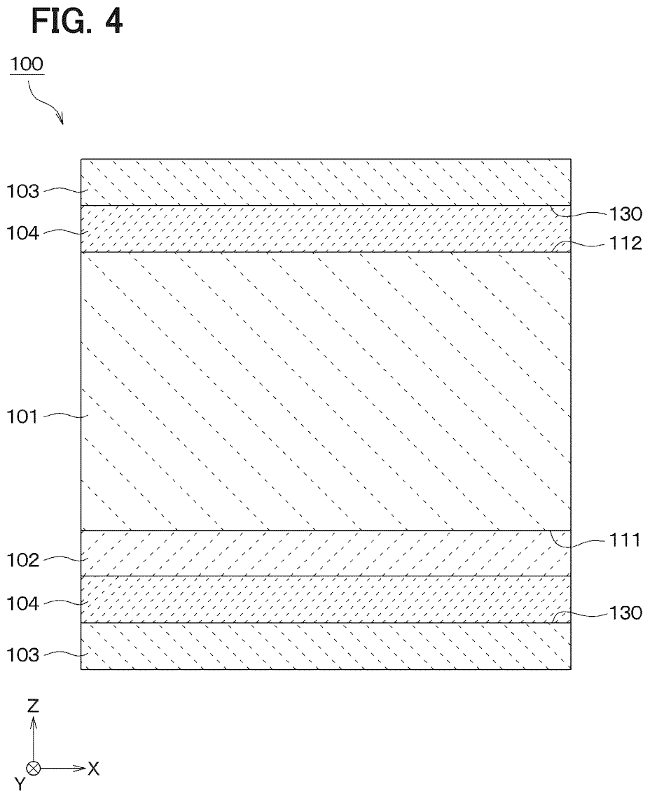

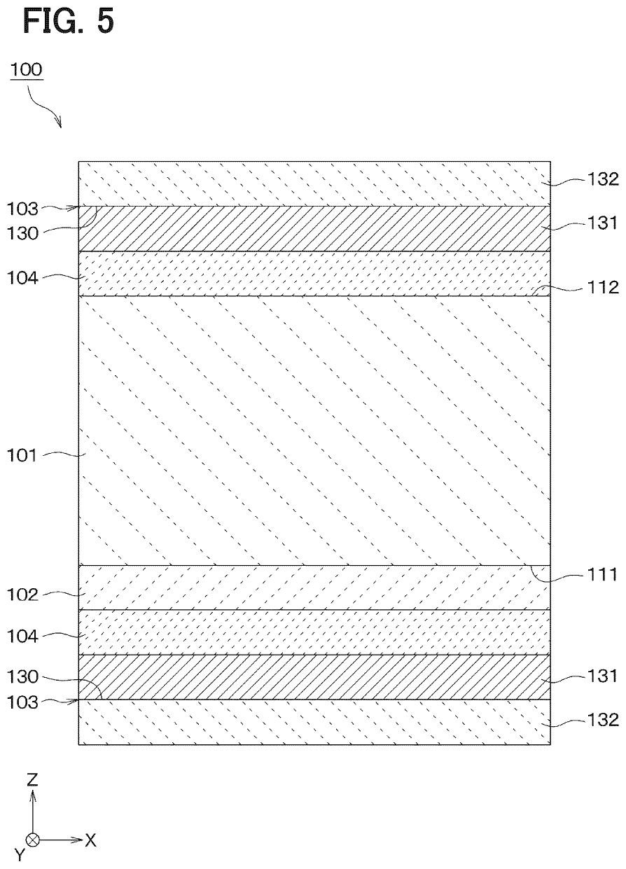

Hereinafter, with reference to FIG. 2, a schematic configuration of the semiconductor stack 100 according to the present embodiment, as well as an outline of the method for manufacturing the semiconductor device 1 using this stack, will be described. The right-handed XYZ coordinate system shown in FIG. 2 is depicted to correspond with the right-handed XYZ coordinate system shown in FIG. 1. The same applies to FIGS. 4 and 5, which correspond to other embodiments described later.

### First Embodiment

As shown in FIG. 2, the semiconductor stack 100 according to the present embodiment includes a nitride semiconductor layer 101, a support substrate 102, and a protective layer 103. The nitride semiconductor layer 101, which is composed of gallium nitride and/or aluminum gallium nitride, corresponds to the semiconductor layer 2 shown in FIG. 1. The nitride semiconductor layer 101 is a compound semiconductor layer to be the base for the drift region 24 to the body contact region 27, and is formed to contain an n-type dopant.

The nitride semiconductor layer 101 is formed by crystal growth on the support substrate 102. The support substrate 102 is provided in contact with a first main surface 111, which is a lower surface of the nitride semiconductor layer 101. The first main surface 111 corresponds to the lower surface 21 in FIG. 1. The support substrate 102 corresponds to the substrate 3 shown in FIG. 1, and contains the n-type dopant at a higher concentration than the nitride semiconductor layer 101.

The protective layer 103 is provided to cover a second main surface 112, which is an upper surface of the nitride semiconductor layer 101. The second main surface 112 corresponds to the upper surface 22 in FIG. 1. In this embodiment, the protective layer 103 is provided to cover the support substrate 102. The protective layer 103 is provided to cover both the upper and lower surfaces of the stack of the nitride semiconductor layer 101 and the support substrate 102.

The protective layer 103 is composed of a material that does not contain oxygen as a constituent element. The material of the protective layer 103 can be selected from among nitrides, carbides, and refractory metals. Preferably, the protective layer 103 is formed to have higher oxygen barrier properties than the aluminum nitride layer, thereby restricting the action of oxygen on the second main surface 112. The nitride contains at least one of aluminum, gallium, scandium, boron, indium, and the like. The carbide may be elemental carbon or a compound containing elements such as tantalum or silicon. The refractory metal may be at least one selected from tantalum, molybdenum, nickel, titanium, copper, iridium, platinum, palladium, ruthenium, chromium, hafnium, tungsten, and the like, or a compound thereof.

In the present embodiment, the protective layer 103 has a configuration as a single-layer gallium nitride layer. Specifically, the bonding surface 130, which is a main surface of the protective layer 103, is formed as a flat gallium nitride substrate polished to a mirror finish with a surface roughness Ra of about 5 nm or less. The substrate-shaped protective layer 103 is provided such that the mirror-finished bonding surface 130 is in close contact with the second main surface 112 and the surface of the support substrate 102.

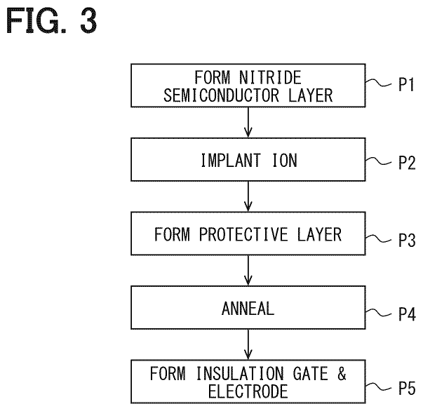

FIG. 3 shows a part of the manufacturing process of the semiconductor device 1 according to the present embodiment. The first to fifth steps P1 to P5 shown in FIG. 3 are merely selected parts of the entire manufacturing process. Therefore, it does not preclude the possibility that other steps not shown in FIG. 3 (for example, a step for removing the protective layer 103) may be inserted before, after, or between the steps.

In the first step P1, the nitride semiconductor layer 101 is epitaxially grown on the upper surface of the support substrate 102 to contain an n-type dopant. As a result, the nitride semiconductor layer 101 having a desired thickness is formed on the support substrate 102.

In the second step P2, using ion implantation technology, a p-type dopant and an n-type dopant are implanted into predetermined regions of the upper portion (adjacent to the second main surface 112) of the nitride semiconductor layer 101. As a result, ion-implanted regions that serve as the basis for the body region 25, the source region 26, and the body contact region 27 shown in FIG. 1 are formed.

In the third step P3, the protective layer 103 is formed on the upper and lower surfaces of the stack of the nitride semiconductor layer 101 and the support substrate 102. The protective layer 103 is intended to suppress roughening on the surface of the nitride semiconductor layer 101, specifically, the second main surface 112, which is not bonded to the support substrate 102. The roughening may be caused by release of nitrogen from the nitride semiconductor layer 101 during subsequent annealing. As a result, the semiconductor stack 100 shown in FIG. 2 is formed.

The protective layer 103 may be formed using crystal growth techniques; however, as described above, it can be easily carried out by employing a method in which the protective layer 103, serving as a flat protective substrate with a mirror-finished bonding surface 130, is brought into close contact. The formation of the protective layer 103 on the support substrate 102 may be omitted as appropriate. It is also acceptable for only the protective layer 103 covering the second main surface 112 of the nitride semiconductor layer 101 to be provided.

In the fourth step P4, annealing is performed by a heat treatment for activating the ion-implanted region. As a result, the implanted dopant, particularly magnesium, which is a p-type dopant, can be effectively activated, and the body region 25, the source region 26, and the body contact region 27 shown in FIG. 1 are formed. After annealing, the protective layer 103 is removed.

In the fifth step P5, the drain electrode 4, the source electrode 5, and the insulation gate 6 are formed. Since the techniques for forming these are already well known as of the filing date of this application, a detailed description will be omitted. In this manner, the semiconductor device 1 shown in FIG. 1 can be manufactured.

The effects achieved by the present embodiment will be described below in comparison with a comparative example.

As a conventional technique, which is the comparative example, it is widely known to use aluminum nitride as the material of the protective layer 103. However, in the conventional technology, there was still room for improvement regarding the protective effect on the surface of the nitride semiconductor layer 101 during annealing, that is, the effect of suppressing the release of nitrogen. Specifically, with protection by an aluminum nitride layer, it was extremely difficult to almost completely suppress pit formation on the surface of the nitride semiconductor layer 101.

More specifically, for example, when the aluminum nitride layer is made thicker, cracks occur during high-temperature heat treatment due to the lattice constant difference between the aluminum nitride layer and the constituent material (e.g., gallium nitride) of the nitride semiconductor layer 101. On the other hand, if the layer is made thinner to avoid the occurrence of such cracks, the effect of suppressing nitrogen release is reduced, resulting in the formation of a large number of pits.

In this regard, as a result of diligent research, the inventors have found that oxygen has an effect on the surface roughening of the nitride semiconductor layer 101. Specifically, regarding annealing conditions where some pits were generated (such as thickness of aluminum nitride layer, ambient gas pressure, temperature, and time), pits were generated over the entire surface when the atmosphere was changed from a nitrogen atmosphere to a nitrogen atmosphere containing a certain amount of oxygen.

Accordingly, the inventors focused on oxygen barrier properties to restrict the action of oxygen on the surface of the nitride semiconductor layer 101. Specifically, the inventors found that by forming the protective layer 103 to have higher oxygen barrier properties than the aluminum nitride layer, the occurrence of pits can be suppressed more effectively, compared with the comparison example. It is preferable to form the protective layer 103 from a material not containing oxygen as a constituent element.

In the present embodiment, the nitride semiconductor layer 101 is composed of gallium nitride and/or aluminum gallium nitride. In this case, by including a gallium nitride layer in the protective layer 103, it is possible to minimize the impact on the nitride semiconductor layer 101 and thereby suppress degradation of device performance extremely effectively. For example, even when a gallium nitride substrate is used as the protective layer 103 and annealing is performed under a pressure exceeding atmospheric pressure (for example, about 1400° C. and 1 GPa), a favorable surface condition of the nitride semiconductor layer 101 can be obtained. Furthermore, it is possible to effectively suppress the influence of oxygen in the ambient gas by reducing the surface roughness Ra of the bonding surface 130, which is the main surface of the substrate-shaped protective layer 103 facing the nitride semiconductor layer 101, to improve the adhesion of the protective layer 103.

### Second Embodiment

In the following description of the second embodiment, the differences from the first embodiment will be explained. In the second embodiment, the parts that are identical or equivalent to those in the first embodiment are designated by the same reference numerals. Accordingly, in the following description, for components denoted by the same reference numerals as those in the first embodiment, the explanations given in the first embodiment may be appropriately applied unless there is a technical inconsistency or a particular need for additional explanation. The same applies to the third embodiment, which will be described later.

FIG. 4 shows a schematic configuration of a semiconductor stack 100 according to the present embodiment. As shown in FIG. 4, in the present embodiment, the semiconductor stack 100 includes an additional protective layer 104 made of aluminum nitride, in addition to the protective layer 103.

The additional protective layer 104 is provided between the nitride semiconductor layer 101 and the protective layer 103. The additional protective layer 104 is formed on the second main surface 112. The protective layer 103 is formed to cover the additional protective layer 104. In other words, the protective layer 103 according to the present disclosure is added to the conventional technique of protecting the nitride semiconductor layer 101 with an aluminum nitride layer. The additional protective layer 104 may also be provided between the support substrate 102 and the protective layer 103.

When the nitride semiconductor layer 101 is composed of gallium nitride and/or aluminum gallium nitride, the constituent materials of the nitride semiconductor layer 101 have low reactivity with aluminum nitride. Therefore, it is possible to very effectively suppress degradation of device performance while minimizing the impact on the nitride semiconductor layer 101. In addition, by employing a two-layer structure consisting of the protective layer 103 and the additional protective layer 104, it is possible to effectively suppress the influence of the ambient gas during annealing and to effectively restrict a decrease in oxygen barrier properties due to the decomposition of the materials contained in the protective layer 103 and the additional protective layer 104.

The protective layer 103 may be a silicon carbide layer instead of a gallium nitride layer. With such a configuration as well, similar effects and advantages can be achieved.

### Third Embodiment

A third embodiment of the present disclosure will be described below. As shown in FIG. 5, in the present embodiment, the protective layer 103 includes a carbon film 131 and a cap layer 132. In addition to the protective layer 103, the semiconductor stack 100 may further include an additional protective layer 104 made of aluminum nitride.

The carbon film 131 is a carbon sputtered film provided to cover the second main surface 112, and is disposed on the inner side of the cap layer 132, that is, adjacent to the nitride semiconductor layer 101. The cap layer 132 is the outermost layer of the protective layer 103 and is provided to overlap on the carbon film 131. The cap layer 132 is formed of a compound semiconductor material such as silicon carbide. With such a configuration, even better heat resistance and oxygen barrier properties can be achieved. Further, when the substrate-shaped cap layer 132 is used, it becomes possible to effectively suppress the influence of oxygen in the ambient gas by reducing the surface roughness Ra of the bonding surface 130, which is the main surface facing the nitride semiconductor layer 101, to improve the adhesion.

### Modification

The present disclosure is not limited to the above embodiments. Therefore, modifications can be made to the above embodiments as appropriate. The following describes representative modification examples. In the following description of modification examples, the differences from the above embodiments will be mainly explained. In addition, in the above embodiments and modification examples, the same reference numerals are given to parts that are identical or equivalent to each other. Accordingly, in the following description of the modification examples, for components having the same reference numerals as those in the above embodiments, the explanations given in the above embodiments may be appropriately applied unless there is a technical inconsistency or a need for special additional explanation.

The present disclosure is not limited to the shapes and structures specifically disclosed in the above embodiments. For example, the semiconductor device 1 may have a so-called trench gate structure. The protective layer 103 may have a multilayer structure with three or more layers. Specifically, the protective layer 103 shown in FIGS. 2 and 4, and the cap layer 132 shown in FIG. 5 may have a multilayer structure. In the case of a multilayer structure, the layers may be composed of the same material with different component ratios, or may be composed of different materials.

The protective layer 103 does not contain oxygen as a constituent element; however, this does not mean that it is completely free of oxygen, and the presence of oxygen at impurity levels is not excluded.

It goes without saying that the components constituting the above embodiment are not necessarily essential, except in cases where it is explicitly stated that they are essential or where it is considered self-evident from the principle that they are essential. In addition, when numerical values such as the number, amount, or range of components are mentioned, the present disclosure is not limited to those specific values, except in cases where it is explicitly stated that they are essential or where it is self-evident from the principle that the disclosure is limited to particular values. Similarly, when the shape, orientation, positional relationship, or the like of components is mentioned, the present disclosure is not limited to such shape, orientation, or positional relationship, except in cases where it is explicitly stated that they are essential, or where it is self-evident from the principle that the disclosure is limited to a particular shape, orientation, positional relationship, or the like.

Modifications are also not limited to the above examples. That is, for example, embodiments other than those exemplified above may also be combined with each other, as long as there is no technical contradiction among the multiple embodiments. Similarly, multiple modifications may also be combined with each other, as long as there is no technical contradiction.

What is claimed is:

1. A semiconductor stack comprising:
a nitride semiconductor layer containing a dopant; and
a protective layer covering a surface of the nitride semiconductor layer, wherein
the protective layer is formed not to contain oxygen as a constituent element, and
the protective layer has an oxygen barrier property higher than that of an aluminum nitride layer, to restrict an action of oxygen on the surface of the nitride semiconductor layer.

2. The semiconductor stack according to claim 1, wherein
the nitride semiconductor layer is made of gallium nitride or aluminum gallium nitride, and
the protective layer includes a gallium nitride layer.

3. The semiconductor stack according to claim 1, wherein
the nitride semiconductor layer is made of gallium nitride or aluminum gallium nitride,
the protective layer includes a carbon film, and a cap layer stacked on the carbon film, and
the cap layer is made of a compound semiconductor material.

4. The semiconductor stack according to claim 3, wherein the cap layer is made of silicon carbide.

5. The semiconductor stack according to claim 1, further comprising: an additional protective layer provided between the nitride semiconductor layer and the protective layer, wherein
the additional protective layer is made of aluminum nitride.

6. The semiconductor stack according to claim 1, wherein
the protective layer has a substrate, and a surface roughness Ra of a surface of the substrate is 5 nm or less.

7. A semiconductor stack comprising:
a nitride semiconductor layer containing a dopant; and
a protective layer covering the nitride semiconductor layer, wherein
the nitride semiconductor layer is made of gallium nitride or aluminum gallium nitride, and
the protective layer is made of:
i) a gallium nitride layer; or
ii) a carbon film and a cap layer stacked on the carbon film, wherein the cap layer is made of a compound semiconductor material.

8. A semiconductor device comprising:
a semiconductor layer including a nitride semiconductor; and
an electrode formed on a surface of the semiconductor layer, wherein a surface roughness Ra of the surface is 5 nm or less.

9. The semiconductor device according to claim 8, wherein
the semiconductor layer is made of gallium nitride or aluminum gallium nitride, and has a region containing a p-type dopant.

10. A method of manufacturing a semiconductor device comprising:
forming a protective layer to cover a surface of a nitride semiconductor layer into which a dopant is ion-implanted; and
annealing the nitride semiconductor layer by heat treatment while protected with the protective layer, wherein
in the forming of the protective layer, the protective layer is formed not to contain oxygen as a constituent element, and to have an oxygen barrier property higher than that of an aluminum nitride layer, to restrict an action of oxygen on the surface of the nitride semiconductor layer.

11. The method according to claim 10, wherein
the nitride semiconductor layer is made of gallium nitride or aluminum gallium nitride, and
the protective layer includes a gallium nitride layer.

12. The method according to claim 10, wherein
the nitride semiconductor layer is made of gallium nitride or aluminum gallium nitride, and
in the forming of the protective layer, a carbon film is formed to cover the surface of the nitride semiconductor layer, and a cap layer made of a compound semiconductor material is stacked on the carbon film.

13. The method according to claim 12, wherein the cap layer is made of silicon carbide.

14. The method according to claim 10, wherein
in the forming of the protective layer, an additional protective layer made of aluminum nitride is formed on the surface of the nitride semiconductor layer, and the protective layer is formed to cover the additional protective layer.

15. The method according to claim 10, wherein the annealing is performed under a pressure exceeding an atmospheric pressure.

16. The method according to claim 10, wherein
the protective layer has a substrate, and a surface roughness Ra of a surface of the substrate is 5 nm or less.
